(19) United States
(12) Patent Application Publication
(10) Pub. No.: US 2014/0265625 A1
(43) Pub. Date: Sep. 18, 2014

(54) Loaded Blumleins

(71) Applicant: COMPACT PARTICLE ACCELERATION CORPORATION, Livermore, CA (US)

(72) Inventors: Cameron Hettler, Livermore, CA (US); Yoko Kawai Parker, Pleasanton, CA (US)

(73) Assignee: Compact Particle Acceleration Corporation, Livermore, CA (US)

(21) Appl. No.: 13/799,132

(22) Filed: Mar. 13, 2013

(51) Int. Cl. H03K 3/53

(52) U.S. Cl. CPC H03K 3/53
USPC 307/106

(57) ABSTRACT

A loaded blumlein structure is described. At one end, the blumlein can be used to generate an electromagnetic pulse. At the other end, the top and bottom conductive connected by a resistive (or more generally a lossy) connection. This allows for subsequent pulses after the initial pulse to be dampened, maintaining the amplitude of the primary pulse, while reducing the stress on the system from the later ringing of the pulse. A number of geometries are described. In other examples, a pulse dampening section connected between the top and bottom conductive strips to provide the dampening effect.

### BACKGROUND

1. Field of the Invention

This application relates generally to circuitry for generating high voltage pulses and, more specifically, to Blumlein structures.

2. Background Information

Particle accelerators are used to increase the energy of electrically charged atomic particles. In addition to their use for basic scientific study, particle accelerators also find use in the development of nuclear fusion devices and for medical applications, such as cancer therapy. One way of forming a particle accelerator is by use of a dielectric wall type of accelerator, an example of which is described in U.S. Pat. No. 5,757,146, that formed out of one or more Blumlein structures. A Blumlein is basically a set of three conductive layer or strips with the two spaces between the strips being filled with dielectric material to produce a pair of parallel transmission lines: the first transmission line is formed by the top and middle conductive strips and the intermediate dielectric layer; the second transmission line is formed by the bottom and middle conductive strips and the intermediate dielectric layer. The common, middle conductive layer is shared by the pair of lines. By holding the upper and lower conductive layers at ground, charging the shared middle layer to a high voltage, and then discharging the middle layer, a pair of waves then travels down the pair of transmission lines. By arranging for this structure for the waves to produce a pulse at one end, the result field can be used to accelerate a particle beam.

Within these various applications, there is an ongoing need to make particle accelerators more powerful, more compact, or both. Consequently, such devices would benefit from improvements in Blumlein technology.

### SUMMARY OF THE INVENTION

According to a first set of general aspects, a blumlein structure to provide an electromagnetic pulse at one of its end has a first planar conductive strip, a second planar conductive strip parallel to the first planar conductive strip, and a third planar conductive strip parallel to the first and second planar conductive strip, where the second planar conductive strip is positioned between the first and third planar conductive strips. The structure includes a switch with first and second terminals are respectively connected to the first and the second planar conductive strips. Dielectric material fills the space between the first and second and the second and third planar conductive strips. The first and third planar conductive strips are electrically connected at the end of the blumlein structure opposite the end from which the electromagnetic pulse is provided, where the electrical connection includes a lossy portion.

In other aspects, a blumlein structure to provide an electromagnetic pulse at one of its end includes a pulse dampening section. The blumlein structure has a first planar conductive strip, a second planar conductive strip parallel to the first planar conductive strip, and a third planar conductive strip parallel to the first and second planar conductive strip, where the second planar conductive strip is positioned between the first and third planar conductive strips. A switch has first and second terminals that are respectively connected to the first and the second planar conductive strips. Dielectric material fills the space between the first and second and the second and third planar conductive strips and there is an electrical connection between the first and third planar conductive strips at the end of the blumlein structure opposite the end from which the electromagnetic pulse is provided. The pulse dampening section connected between the first and third conductive strips to provide an additional electrical connection between them, where the additional electrical connection includes a lossy portion.

Various aspects, advantages, features and embodiments of the present invention are included in the following description of exemplary examples thereof, which description should be taken in conjunction with the accompanying drawings. All patents, patent applications, articles, other publications, documents and things referenced herein are hereby incorporated herein by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWINGS

FIG. 1 shows one exemplary embodiment for a blumlein module.

FIG. 2 is a cross-section view of the central portion of the embodiment of FIG. 1.

FIGS. 3a-c illustrate a number of different interfaces of materials between conductors.

FIGS. 4a and 4b illustrate an embodiment for a switch module assembly.

FIG. 4c shows several possible switch profiles.

FIGS. 5a-d illustrate the placement of the switch module of FIGS. 4a and 4b into the blumlein embodiment of FIGS. 1 and 2.

FIG. 6 shows an alternate embodiment of a switch module.

FIG. 7 shows components of an alternate blumlein embodiment using the switch module of FIG. 6.

FIG. 8 is an enlarged view of the assembled central portion of the embodiment illustrated in FIG. 7.

FIG. 9 illustrates a blumlein structure with a thicker spacing for the top dielectric to accommodate a thicker switch.

FIGS. 10a and 10b show a blumlein with a necking structure for the switch.

FIG. 11 shows a blumlein with a tab structure for the switch.

FIGS. 12 shows a typically blumlein structure.

FIGS. 13 and 14 compare the operation of a typical blumlein with a loaded blumlein.

FIG. 15 illustrates a loaded blumlein.

FIGS. 16-19 show several alternate geometries for loaded blumleins.

FIG. 20 shows an example of a blumlein using a stem structure for dampening the output.

### DETAILED DESCRIPTION

FIG. 1 is a first exemplary embodiment in which the various aspects presented here can be applied. FIG. 2 is a side view of the center portion of a cross-section through the middle of the same embodiment, taken along the axis indicated along A in FIG. 1. Referring first to FIG. 2, the blumlein module is formed a top conducting strip 101, a middle conducting strip 103, and a bottom conducting strip 105 that run parallel from left to right with uniform spacing between each pair. The space between the middle conductive strip 103 and the bottom conductive strip 105 is filled with dielectric material to form the bottom transmission line. Here the dielectric is formed of three components, 111, 113, and 115, for reasons that will be explained below, but in other embodiments this can be a single element. The top transmission line is formed by the top (101) and middle (103) conductive strips with the space in between filled with switch structure or module with dielectric material 121 and 125 on either side. The switch module structure is formed of the switch 131 itself, having electrical contacts 143 and 141 on the top and bottom respectively connected to the top and middle conductive strips, and a holder or connector 133 and 135 on either side where the switch interfaces the dielectrics 121 and 125. The blumlein module can then be used for forming a particle accelerator, where several such modules are often stacked, as well as other application that need a pulsed, high-voltage energy source, such as a radar transmitter, for example.

In the embodiment of FIGS. 1 and 2, the bottom dielectric (111, 113, 115) and the top dielectric (101, 103) are taken to be of the same thickness and of the same material. More generally, other arrangement may be used, as may other geometries, but the shown arrangement is useful for discussing the various aspects presented below. More detail and other examples can be found in US patent publication number 2010/0032580 and U.S. Pat. Nos. 5,757,146; 5,511,944; and 7,174,485. More detail on a suitable switch 131 is described: G. Caporaso, “New Trends in Induction Accelerator Technology”, Proceeding of the International Workshop on Recent Progress in Induction Linacs, Tsukuba, Japan, 2003; G. Caporaso, et. al., Nucl Instr. and Meth. in Phys. B 261, p. 777 (2007); G. Caporaso, et. al., “High Gradient Induction Accelerator”, PAC'07, Albuquerque, June 2007; G. Caporaso, et. al., “Status of the Dielectric Wall Accelerator”, PAC'09, Vancouver, Canada, May 2009; J. Sullivan and J. Stanley, “6H-SiC Photoconductive Switches Triggered Below Bandgap Wavelengths”, Power Modulator Symposium and 2006 High Voltage Workshop, Washington, D.C. 2006, p. 215 (2006); James S. Sullivan and Joel R. Stanley, “Wide Bandgap Extrinsic Photoconductive Switches” IEEE Transactions on Plasma Science, Vol. 36, no. 5, October 2008; and Gyawali, S. Fessler, C. M. Nunnally, W. C. Islam, N. E., “Comparative Study of Compensated Wide Band Gap Photo Conductive Switch Material for Extrinsic Mode Operations”, Proceedings of the 2008 IEEE International Power Modulators and High Voltage Conference, 27-31 May 2008, pp. 5-8. Further examples of using such a switch in a high voltage, radio frequency opto-electric multiplies for charged particle accelerators is described in U.S. patent application Ser. No. 13/352,187.

Referring back to FIG. 1, the exemplary switch structure is light activated by laser light as supplied by the optic fibers 141 and 143 that are held on the sides of the switch 131 by the ferules 137 and 139, respectively. The middle portion 113 of the bottom dielectric extends to the sides to help support the fibers 145 and 147 and can also serve a heat sink function. The upper conductive strip 101 and lower conductive strip 105 are electrically connected on the left side of FIG. 1. Several such blumlein modules can then be stacked to form an accelerator.

Unlike the arrangement of the blumleins described in the references cited above, where the switch structure is placed off to the end of the module, in the exemplary embodiments the switch is centrally placed between the top and middle conductive strips. Because of this difference, a brief description its operation will now be given. Referring to FIG. 1, assume that the accelerator is on the right side of the blumlein, or, more generally in the case of other applications, that the pulse to be presented on the right hand side. The one transmission line is the right “wing” of the top half (the dielectric 125 between the top conducting strip 101 and middle conducting strip 103 to the right of the switch module), and the second transmission line is the left “wing” of the top half of the left “wing” (to the left of the switch) plus the whole transmission line on the bottom (along dielectrics 111, 113, 115), which comprises the bottoms of the right and left “wings”. Initially the top and bottom conductive strips (101, 105) are at ground and the middle conductive strip 103 is at a high voltage. The switch is then turned on.

The pulse generated by the switch start moving in both directions away from the switch in the top transmission lines. The left wings of the top and of the bottom lines are connected by a low resistance, which can just a short connection between them; for example, the connection can go through a hole or metalized via through the body of the blumlein. Consequently, the pulse will continue to move back to the right in the “bottom” transmission line after it reaches the end at the left top line, but its electric field is now upside-down. The right ends of the bottom and the top transmission lines are not connected (there is a high resistance between them). Because of this, the pulse will be reflected when it reaches the right end of the right top transmission line and start moving towards the switch. When this reflected pulse reaches the switch (that is still open, so its resistance is low), the pulse will be reflected again but with 180 degree shifted phase, which means that its polarity will be opposite (its electric field turned over also). The second time reflected pulse will be moving toward the accelerator and will get the accelerator at the same time when bottom pulse will get there. Sum of these two pulses will make a pulse with a double voltage amplitude.

Under the arrangement of FIGS. 1 and 2, the switch 131 is itself placed between top conductive strip and the central conductive strip. Consequently, the switch is subjected to high electric field values. As the dielectric constant of the switch will typically not match that of the adjoining dielectric material, this can lead to charge accumulation at the interface between these. This problem is considered in the following section. For a light activated switch, such as that of the exemplary embodiment, another problem is that the ferrules used to provide the illumination source also need to be able to handle the high field levels while still providing sufficient light. The arrangement of the ferrules is then considered in a subsequent section.

Blumlein with Encapsulated Solid-State Switch

This section considers in more detail some techniques for building blumlein devices where materials bonded together and whose interface operates under very high electrical fields, over 30 kV/mm for example. The weakest part of high voltage devices is often an interface between bonded materials with different dielectric constants. Electrical charge tends to accumulates at the interface, due to difference in permittivity of joint media and due to local high electrical fields created by imperfections at the interface. The higher electrical field, which is produced by the extra charge, and higher charge mobility along the interface, increase the probability of the electrical breakdown through the interface. The methods described here minimize these problems and allow for the building of blumlein devices with encapsulated solid state switches.

Considering the problem itself further, FIG. 3a shows the interface 305 of length L between bonded materials M1 301 and M2 303, which is inserted into electrical field E=Uo/∈d, where ∈ is an effective permittivity at the interface 305, that is created by powering the metal contacts/terminals on top plate 307 and at the bottom plate 309 of the device that are separated by a distance d to a voltage difference of Uo. Here M1 301 and M2 303 respectively correspond to the dielectric 121 and the switch 131 of FIGS. 1 and 2. In a typical implementation, d may be on the order ˜1 mm and Uo may 25 kV up to 100 kV. The interface boundary 305 is orthogonal or normal to the surface of the upper and lower plates (307, 309), so that d is the same as L. In this case, the electrical field along the interface is the same as it is across the body of the device. Dielectric materials can usually be optimized for high voltage applications and there are number of available materials that can withstand electrical fields over 30-100 kV/mm. In the exemplary embodiments the body of the switch is formed a semiconductor, specifically silicon carbide, so that there will typically be a mismatch between the permittivity between it and the dielectric of the blumlein transmission line.

The simple interface arrangement shown in FIG. 3a can usually withstand electrical fields only up to about 10 kV/mm. To withstand higher values, the exemplary embodiments use developed interfaces between bonded materials. FIGS. 3b and 3c present examples of such developed interfaces, where the first of these has a diagonal interface 305′ and the second a stepped interface 305″. Preferably, the sharp corners in an arrangement such as FIG. 3c are rounded somewhat, but this is usually obtained as a result of fabricating process. In either of these cases, the effective electrical field along the interface is E=Uo/∈L, so that the ability of the interface to withstand high voltages is improved by this increasing the interface length L by having at least a portion of the interface running in a direction that is non-orthogonal between the conducting surfaces.

The exemplary switch used here is an optically activated semiconductor switch formed largely of silicon carbide, but in other embodiments could be of a semiconductor material, such as GaN, AlN, ZnSe, ZnO, diamond, doped glasses, semiconductor particles/crystallites embedded into insulator materials, and so on. For any of these, there will typically be a resultant mismatch in permittivity between it and the adjacent dielectric used in the blumlein's upper transmission line. Such a switch will often come rectangularly shaped, more or less, so that if directly bonded to the dielectric it would present the sort of cross-section shown in FIG. 3a. As the switch itself may not readily be shaped (or reshaped) to have a different profile, rather than have the switch directly adjoining the dielectric, a connecting structure, or carrying unit, is used as part of the switch module for this purpose. The formation of a switch module is illustrated with respect to FIGS. 4a and 4b.

FIG. 4a shows an assembled switch module structure for the opto-switch 131 to be placed into the blumlein and FIG. 4b shows an exploded view of the elements. The module includes the connectors 135 and 133 and the ferrules 139 and 137. The ferrules 137 and 139 can be used to maintain optical fibers for triggering the switch as well as for a heat sink. The optical fibers, and hence the ferrules, are discussed further in the next section and are used as the exemplary switch 131 is optically activated, but would not be required in other embodiments where the switch 131 is otherwise activated. In this particular version, which corresponds to the embodiment of FIGS. 1 and 2, the connectors 133 and 135 and ferrules 137 and 139 are separately elements, but in other embodiments (such as discussed further below) they can be a solid unit instead of using an assembly. The overall dimensions of units 133, 135 and 137, 139 can vary depending on particular design. The solid state switch 131 has with terminal T 143 and a similar terminal 141 on its underside. Once the elements shown in FIG. 4b are assembled contacts C 153 and a similar contact (151, see FIG. 5a) on the bottom can be added to the module assembly, as shown in FIG. 4a. The module contacts are here plated after module has bonded. (In FIG. 2, the contact C 153 is not shown separately, but can be taken as part of the upper conducting strip 101, with the bottom contact similarly incorporated into the middle strip 103.)

The side portions 133 and 135 of the module can be formed of a material having a permittivity close to that of the switch material. For example, these could be made of epoxy, as could the ferrules 137, 139. Because of this, although the profile of the switch 131 may result in the interface between it and the connectors 133 and 135 being as in FIG. 3a, the relatively similar permittivity values shift the problem to the interface between the connectors 133 and 135 and the dielectric of the transmission, such as 121 and 125, respectively, in FIGS. 1 and 2. As both the connectors and the dielectric will usually be able to have their shapes easily formed into more arbitrary shapes than the switch, the can have an elongated interface having a portion that is substantially non-orthogonal to the conducting surfaces, such as those shown in FIGS. 3b and 3c.

Although the discussion here is for the encapsulation of a switch within a blumlein structure, the same technique can similarly be applied to other cases where two elements need to have an interface between to such conductors at a high voltage difference, but have differing permittivity values. For the element with a relatively short interface between the plates, another material having a relative similar permittivity can be introduced to allow this interface to withstand higher field values. The other element can then have its interface with introduced connecting material shaped to increase this interface that will then have the greater discontinuity in permittivity values. Additionally, although the profile of the switch 131 in the example is taken to be like that on the left of FIG. 4c, it may have other profiles, with examples shown center and right. In these case, although the shape of the switches will allow them to withstand higher field levels and remove the need for the elements 133 and 135 of the module, the use of such connectors can be to further increase the field strengths the interface can handle, both further lengthening the interface and also splitting up the amount of transition in relative permittivity change over two transitions. Aside from these considerations, the use of such a module can be useful for placing the switch within the blumlein as silicon carbide does not readily bond to many other materials.

FIG. 5a is a down-up view for the same module assembly as in FIG. 4a. This module can then be inserted into a blumlein and the whole assembly coupled optical fibers F 145 and 147, as shown in FIG. 1. It also includes a heat sink unit/support 113 as shown in FIG. 5b, which includes a portion of the bottom conductive strip 105, and two blumlein wings as shown in FIG. 5d. One example of the assembling procedure is shown in FIG. 5c: first, the ferrules 137 and 139 are bonded to the switch, followed by bonding units 133 and 135 to the assembly. Then module can bonded to the blumlein wings. After that, electrical contact between module contacts and blumlein strip lines have to be established. It is important that the assembly allows access to the top and middle strips of the blumlein to complete formation of the upper and middle conductive strips 101 and 103. After this is the bonding of the heat sink unit 113 to the assembly, followed by making electrical contact between bottom strip of the heat sink unit 113 and bottom strips of the blumlein to complete the bottom conducting strip 105.

### Optical Coupling of Switch to Light Source

As noted above, the exemplary embodiment of a blumlein structure uses a light activated switch. This section considers the coupling of the illumination to the switch. Although the exemplary embodiment uses the side connector structures 133 and 135 discussed in the last section as well as the ferrules 137 and 139 discussed in this section, more generally, these as independent aspects. For example, the switch may be light activated, but not require the connector structures 133 and 135; conversely, these side connectors can be used for switch that is activated by other means not requiring the optic fibers.

To activate the switch, it needs to be sufficiently illuminated. This can be done by use of the ferrules, placed on either side of the switch, holding optical fibers so that they optically couple to the switch. The other ends of the fibers could then be illuminated by a laser, for example, to effect turning the switch on and off. The amount of light on the switch will then be based on the number of fibers, their cross-sections, and the intensity of the light. As the ferrules with be subjected to the field between the upper and middle conductive strips of the blumlein, they will need to be able to support this field without breaking down. The more space given over to the optical fibers, the less field it will be able to support. On this basis, it makes sense to reduce the number, cross section, or both, of the fibers; however, this would require an increase in the intensity of light. Also, having too many fibers increases the complexity of the design. As the switch can only withstand a certain level of fluence, or light energy per area, on its surface before the switch is damaged, the intensity of the light must be balanced against the number and size for the fibers. Similarly, although increasing the width of the conducing strips can provide a larger pulse from the blumlein, this will place more of ferrules under a higher field. Consequently, a number factors need to be balanced when optimizing the design.

As shown in FIG. 4b, for example, the ferrule portions 137 and 139 of the switch module assembly has several holes for the insertion of the optical fibers, shown as 145 and 147 in FIG. 1. Although larger openings would allow for larger fibers, and correspondingly more illumination on the switch 131, this would make the ferrules breakdown at lower field strengths. (In the example, the openings are round, as this shape is useful when round optic fibers are used, but rectangular or other shaped openings could also be used.) In one of the principle aspect of this section, top and central conducting strips are formed so that the switch is allowed to extend laterally to either side before the interface with the ferrules, allowing a margin so that ferrules are not placed directly between the plates. Although the ferrules still be subjected high filed levels, this will reduce it below the full strength between the plates. As to the width selected for the conductive, this is again a design choice as the wider the conductive strips, the stronger the pulsed that can be produced, but a wider strip then makes the ferrules more likely to break down.

In the exemplary embodiment for the switch module described with respect to FIGS. 4a and 4b, the ferrules 137 and 139 each hold four fibers; and although the figures are not fully to scale, the do illustrate the relative size of the openings to the ferrule as a whole. Any bonding agent for the fibers to the switch would need to be transparent. The exemplary switch is formed of silicon carbide. As the fibers cannot be readily bonded to this material, the ferrules are used to mechanically the bond the fibers by holding them up to the switch. The ferrules can be made of the same material as the side pieces 133 and 135, such as epoxy. In the embodiments discussed so far, the side pieces 133, 135 and ferrules 137, 139 are formed separately and then joined together. This is convenient for discussing the independent aspects associate with each of this elements and although it is preferred in some applications, in other cases it is preferable that these elements of the switch module are formed of a single piece. Such a unified embodiment for the switch holder is discussed in the next section.

Single Piece Holder with Ferrules

FIGS. 6 shows a top and bottom view of switch module 500 respectively at top and bottom. The silicon carbide (or other semiconductor) switch 501 is placed into the monolithic dielectric switch carrier 503. Here the holder 503 includes both the shape having a non-orthogonal ends where it will interface with the dielectric and a set of 6, in this version, openings for optic fibers on each of the sides. In other embodiments, if the switch is not light activated, the holder need not have the ferrule function and the holes could be eliminated and, if desired, the conductive strips could be widened; conversly, if the elongated end profile is not needed due to mismatch in permittivities, the ends could be square will the holder would still perform the ferrule function. The space between the switch 501 and holder 503 can then be filled in with epoxy or other filler 511. The a portion 507 of the top conductive strip and a portion 509 of the bottom conductive strip run along the outside of the module are formed of, for example, copper. The contact terminals are shown at 505 for illustration purposes, although these are actually below the strips 507 and 509.

FIG. 7 shows an exploded view of a blumlein structure for this embodiment. The top portion 507 of the conductive strip of the switch module assembly is connected to the rest of the top planar conductive strip 521 having left and right portions and which can again be made of copper or other conductor. The top dielectric strip 523 again has left and right wings and can be made of Cirlex® or kapton, for example. In this embodiment, a bonding layer 525 is then between the top dielectric strip 523 and the middle planar conductive strip 527, where each again has left and right portions and the thin dielectric buffer layer 525 can be applied to bond layers such 523, 527 and 529 together. The middle planar conductive strip wings can again be of copper or other conductive material and will connect together through the bottom contact strip 529 of the switch module. The bottom dielectric layer is formed of the dielectric strip 531, again with two wings, and a central portion made of the support 533, where these could again be of Cirlex® or kapton, for example. The bottom planar conductive strip can again be of copper or other suitable conductor and is here formed of a first part 531 of left and right wings and also a middle piece 535 for under the support 533. Rather than have a single piece for the bottom semiconductor layer, it is often convenient to use the support 513 as this can support the fibers as they feed into the ferrules, as well as being useful for mounting the blumlein modules and serving a heat sinking function. The central portion of the blumlein structure when assembled is shown in an enlarged view in FIG. 8. The embodiment in FIGS. 7 and 8 is again evenly spaced between the pairs of conductors, symmetric in that the switch is centrally located, and uses the same material for the dielectrics in both the top and bottom transmission lines, but other embodiment can use other arrangements for any of these.

The various aspects described above are presented further in U.S. patent application Ser. No. 12/963,456.

### Switch Placement

This section considers the geometry of the blumlein and how the switch is placed within the blumlein structure. The thicker the switch, the higher the voltage it charged to without breaking down. A thicker switch can also provide a larger surface to illuminate. Although the sort of improvements described in U.S. provisional application No. 61/680,782 can increase both the voltage that can placed across the switch and also improve the optical response of the switch, being able to have a thicker switch can make for a better blumlein. (The next section also considers illumination.) On the other hand, the thinner the blumlein, the higher the electric field it can provide and the thinner a stack of blumleins, such as used in an accelerator, can be. This section considers a technique to overcome these two seemly contradictory aims by presenting a way to fit a thick switch into a thin blumlein. By combining the two, thin blumleins can be charged to high voltages and achieve very high accelerating gradients by gaining from both higher a charge voltage as well as the higher electric field and therefore produce a very compact accelerator.

The exemplary embodiments in the following discussion of this section will again be based on the sort of optically activated switch discussed above, although other forms of solid state switch could be used. The various other aspects also described above are also complimentary in that although they can be combined with the aspects of this section, the techniques of this section can also be used independently of them.

FIG. 9 illustrates some of the relevant elements of a blumlein. Here the optical connections and other feature of the switch module are suppressed to simplify the discussion. The switch 601 is placed between the top conductor 603 and middle conductor 605, where the rest of the space in between is filled with the dielectric 611. The bottom conductor is shown at 607, with the space between it and the middle conductor 605 filled with dielectric 613. The top conductor 603 and bottom conductor 607 are then connected at on end (here on the right) and then can be grounded at the other end. Here the blumlein is a length l with a switch is located at the center. The top dielectric layer 611 has a width wₗ, which is wider than the lower dielectric 613 with a width w₂, in order to allow for a thicker switch, but at the cost making the blumlein wider. The width of the blumlein can be decreased by squeezing it down away from the switch, so that it is narrowing at the ends; but this does not allow for multiple such blumleins to be stacked any more closely. If these switches are displaced to the side, but not all at the same point, then the individual blumleins can be stacked. Examples of this are illustrated in FIGS. 10 and 11.

FIGS. 10a and 10b illustrate a first exemplary embodiment for displacing the switch modules to the sides of the of the blumlein structures in a “necking” arrangement. FIG. 10a shows this arrangement from above. The top conductor 701 of the top-most blumlein stack is shown along with the switch 703, with the rest of the top-most blumlein underneath. The switch region curves out a distance to the side (downward in FIG. 10a). The next blumlein down in the stack is displaced the other direction, where the top conductor 711 and switch 713 can be seen. The stack of blumleins can then alternate sides, allowing for the switch region to each have a greater thickness. FIG. 10b shows an example of this in a side view of the top most blumlein, where the middle conductor 705 and bottom conductor 707 are straight, while the top conductor 701 bulges upward, for example, to hold a thicker switch 703.

In FIG. 10a, each of the blumleins has total length/and the switch region curves outward of over a length l₁ for a displacement l_{off}. Taking into account the offsets, for blumleins of a width w₁ of this makes for a width of w₂. In the example of FIG. 10a, the sideways displacements are all of the same amount l_{off} and are all the same distance along the blumleins at the center. More generally, differing amounts of sideways displacement can be used for the different blumleins displace to each side, allowing for more access to the switches. (This could be used to provide easier access to the top or bottom of the switches, such as could be used in the sort of illumination arrangement described in U.S. provisional application No. 61/680,782.) Alternately, or additionally, the offset can be displaced at differing locations along the length of the blumleins.

FIG. 11 illustrates a second exemplary embodiment for displacing the switch module to the side of the of the blumlein structure. In FIG. 11 a tab structure is used: the top, middle and bottom conductors are all straight, but the top and middle conductors each include tabs, between which the switch is placed. As the bottom conductor is not connected directly to the switch contacts, it does not need to have the tab. FIG. 11 again shows a top view, where the top blumlein's top conductor 801 has a tab 805 of width w_{tab} and length l_{tab}, under which is the switch 803. The tab of the next blumlein down is at 815, where the tabs can alternate sides down the stack. This again allows for a thicker switch. The tabs of FIG. 11 are shown to be symmetric between the two sides, all with the same sideways displacement, and all centrally located, but as with the embodiment of FIG. 10a different amounts of displacement can be used for different blumleins down the stack, both to the sides and down the length of the blumlein.

Altering of the geometry of the blumleins to place the switches off the to the sides, as in FIGS. 10a and 11, can decrease the efficiency of each blumlein, in terms of the amount of maximum electric field that can be generated for a given voltage, this is more than offset by being able to use a higher voltage across the switch and to be able to have shorter stack of blumleins.

### Loading of Blumlein

The preceding sections, which are further developed in US patent publication 2012-0146553 and application Ser. Nos. 13/610,051 and 13/610,069, have focused mainly on the placement and illumination of the switch within the blumlein. This section looks at the conductive portions of the blumlein structure and techniques for providing improvements of the generated pulse by loading the blumlein. In the following, the exemplary embodiments will again have the switch placed between conductive portions of the blumlein; more generally, however, other switch arrangements can be used as the concern here is on the conductive strips themselves and how these are connected.

FIG. 12 is a schematic representation of a single blumlein structure such described above. Between a top conducting strip 903 and a bottom 905 is a middle conducting strip 907, where the area in between these is filled with dielectric material 909. To generate a pulse, a voltage difference is applied between the upper and lower conductors (903, 905), that are here set to ground, and center conductor, which is charged to a voltage +V. (The following discussion is based on a positive high voltage, but negative voltages can also be used.) A switch SW 901 is connected between the top and central strips. (Here the switch is between these two conductive strips, such as is discussed above, but could also be outside with the corresponding area between the strips also filled with the dielectric 909.) When the switch is turned on, a pulse then travels off in either direction as indicated by the arrows. At the left end, the upper conducting strip 903 and lower conducting strip 905 have traditionally been connected. This result in a series of pulses at the left end of the structure at the bracket. As also discussed above, a number of these individual blumleins can be stacked in a pulse generating system, such as a particle accelerator where the top and bottom strips would end in ring electrodes (or equilibration rings) aligned along the accelerators axis.

Due to the structure of blumlein, in addition to an initial pulse after turning on the switch, the output will be a series of pulses that decrease over time due to “ringing” of the structure. This is shown in FIG. 13 at 1001: after an initial pulse, indicated by the right moving bump in FIG. 12 and the well-defined initial pulse of 1001, a series of subsequent pulses follow. These subsequent voltage peaks can place large amounts of stress on the system, as represented in FIG. 14 that shows voltage levels across the switch.

In FIG. 14, 1005 illustrates the voltage across the switch. In initially, a voltage (corresponding to the +V across SW 901 in FIG. 12) of 18.2 kV, for example, is place across the switch. Once the switch is made to conduct, it is then subjected to a rapidly oscillating high voltage signal that places a large stress on the system. This section introduces a loaded blumlein structure to reduce these stress by damping these oscillations, but still retaining the amplitude of the initial output pulse. In FIG. 13, an example of the desired sort of behavior is shown at 1003, which is the same as 1001 for the initial pulse, but then is contained within an envelope that dampens out the oscillations relative to the typical behavior shown at 1001. The resulting stress on the switch is shown at 1007 of FIG. 14 where, relative to 1005, the amount of stress is significantly reduced.

In a set of general aspects, this desired behavior is obtained by “loading” the blumlein. Referring back to FIG. 12, in the traditional blumlein structure the top conducting strip 903 is connected to the bottom conducting strip 905 at the right end by a conductive path. Here, the blumlein is loaded by placing a resistance, or, more generally, a lossy medium, in the way of this connection. For example, in one embodiment the section of the top strip indicated at 911 could be made resistive. In this way, the initial output pulse when the switch SW 901 is turned on (travelling to the right in FIG. 12) is unaffected, but the lossy region at 911 will dissipate the energy of subsequent pulses, placing the desired envelope on output and providing the sort of behavior shown at 1003 and 1007 of FIGS. 13 and 14, respectively. The consequent reduction is stress on the switch can lead to higher switch breakdown voltages than in the traditional blumlein due to lower switch current and damped voltage reflections at both the output and the switch. The loading of the blumlein, and resultant damping of oscillations, can be implemented in a number of ways.

FIG. 15 illustrates the idea for a specific embodiment that moves the load to the back of the blumlein. In FIG. 15, the top conducting strip 1103, middle strip 1107 and bottom strip 1005 are seen separately from above. The switch structure is indicated at 1101. When the structure is assembled, the top and bottom conductors can then be connected by way of the openings indicated at 1115 and 1117. In this example, the load is split between a carbon resistor segment 1111 on the top strip and a carbon resistor segment 1113 on the bottom strip. In this example, both segments 1111 and 1113 are both given a value of 4Ω, where the inherent impedance of the blumlein structure (aside from these resistive segments) is something like 10Ω.

This arrangement can provide a number of benefits. For one, the switch's power consumption is significantly reduced, particularly if dV/dt heating is a significant component. As the dampening does not affect the initial pulse, the primary peak amplitude is not reduced. Further, by careful load design, the reflections could be eliminated entirely.

The load can be implemented in a number of ways, such as fabricating the “loading” resistors on the boards with carbon screen printed resistors. For example, this can be done using carbon ink resistors that can be screen printed on the order of mil thick and then backed to permanently stabilize them. Although FIG. 15 shows resistive sections for both the top 1103 and bottom 1105 strips, this could be included in only one of these, or alternately (or additionally) in the connection between the top and bottom conducting strips. The resistance could also be a volumetric resistance (such as a carbon block) between the top and bottom strips or embedded within the dielectric material. In addition to carbon, the resistance can also be implemented through ceramic, metal film resistance or other media. More generally, rather than a resistance, the load can also be a more general “resistive” or “lossy”, rather than a frequency “ohmic” material. For example, the load could use a material that has frequency dependent absorption, such as ferromagnetic or ferrimagnetic materials.

With respective to amount of resistance, loosely speaking, in many applications this will be of a similar magnitude to the impedance of the transmission lines and, depending on the implementation, may be lower or higher than the impedance of the transmission lines. The resistance value is selected to obtain the desired dampening of the electromagnetic pulse train and, as a practical matter, is somewhat experimentally determined. The resistance is optimized in order to maximize the accelerating gradient while minimizing switch stress, which is a function of the number of blumlein voltage swings per ignition, switch current and possible other considerations. As such, the balance between accelerating gradient and switch stress is a design decision. For example, in a dielectric wall accelerator application, as the resistance affects the acceleration field and number of the swings, the optimum resistance depends on the system configurations.

For any of these arrangements, the load can dampen the oscillations without reducing the accelerating field. In addition to reducing switch power consumption, this also allows for using higher voltage on the switches, extending switch life, or both. For applications such as particle accelerators that stack multiple blumlein structures, this can help to reduce the number of blumleins needed by placing switches in parallel.

In FIG. 15, the conducting strips are of uniform width along their length, but a number of various geometries can be used for the loaded blumlein structure (or for the traditional, non-loaded version as well. FIG. 16 illustrates one example, showing the blumlein from above. In FIG. 16, the switch 1201 is again located under the middle portion of the top conducting strip, but the strip is no longer taken to be uniform along its length. The output, or front, side 1203 that supplies the initial pulse is tapered from the switch region to front end. The rear side 1204 of the blumlein, which does not provide the initial output pulse, can be narrower. In this example, the load is a sheet resistor 1211 at the end of the rear section 1204. The top, middle, and bottom conducting strips can all be similarly narrowed and tapered. The narrowed side of the middle conductor can be ended anywhere between the switch end to the connecting point of top and bottom conductors; that is, the middle conductor ban be made shorter than the top and bottom conducting strips, so that when it is ended at the switch 1201 the middle conductor does not have the narrowed end.

FIGS. 17-19 show several variations on the placement of the load, where the blumlein structure is again shown from above. In each case, the output end 1203 of the top conducting strip is taken to be of uniform width, where FIG. 19 explicitly shows this ending in an equilibration ring. To the left of the switch 1201, the resistive (or, more generally, lossy) section 1211 and conductive portion 1204 of the rear end of the top strip can arrange the load in various ways. In FIG. 17, a relatively small section 1211 of blumlein top and bottom conductors are made of ohmic sheet or other lossy material. In FIG. 18, a larger section 1211 of the blumlein's top and bottom conductor is made of ohmic sheet or other lossy material. FIG. 19 illustrates an example where all of the rear section of the blumlein's top and bottom conductors are made of ohmic sheet or other lossy material.

Another alternative for dampening the output is to not load the top and/or bottom conducting strip, but to a pulse dampening section connected between the top and bottom conducting strips. FIG. 20 illustrates such a blumlein structure as seem from above, where the switch 1301 is again located under the central region of the top conducting strip, where the rear portion 1304 is narrower than the front portion 1303, which ends in the equilibration ring 1323. In this example, none of these elements are loaded, although this could be in a sort of hybrid arrangement. The pulse damping section is implemented as a stem 1331 electrically connecting the blumlein's top and bottom conductors, where in this embodiment the stem connects them at the equilibration rings so as to not attenuation the initial pulse. A part 1333 or all of the stem 1331 can be made of ohmic sheet or other lossy material as described above. The relative dimensions of the stem 1331 are such that the characteristic impedance of the stem is on the same magnitude or higher of the main blumlein. The length should have an electrical length such that the reflections from the stem do not distort the accelerating pulse shape; for instance, the length can be the same as the distance from the switch to the output end. The width can be less than half of that of conductor 1303 width of output end. The location of the can be through a connection near the output end, here the rings 1333. There can be a number of angles, exit locations, and so on, but most would be concentrated near the end of the blumlein or at the equilibration rings.

### CONCLUSION

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

It is claimed:

1. A blumlein structure to provide an electromagnetic pulse at an end thereof, comprising:
a first planar conductive strip;
a second planar conductive strip parallel to the first planar conductive strip;
a third planar conductive strip parallel to the first and second planar conductive strip, where the second planar conductive strip is positioned between the first and third planar conductive strips;
a switch with first and second terminals are respectively connected to the first and the second planar conductive strips;
dielectric material filling the space between the first and second and the second and third planar conductive strips; and
an electrical connection between the first and third planar conductive strips at an end of the blumlein structure opposite the end from which the electromagnetic pulse is provided, where the electrical connection includes a lossy portion.

2. The blumlein structure of claim 1, wherein the switch is placed at least partially between the first and the second planar conductive strips.

3. The blumlein structure of claim 1, further including charging circuitry connected to the conductive strip, where, with first the switch open, the second conductive strip is charged to a first voltage relative to the first and third voltage are held to second voltage, the electromagnetic pulse being generated by subsequently closing the switch, wherein the lossy portion dampens the amplitude of the electromagnetic pulse subsequent to an initial peak.

4. The blumlein structure of claim 3, wherein the second voltage is ground and the first voltage is a positive high voltage.

5. The blumlein structure of claim 3, wherein the second voltage is ground and the first voltage is a negative high voltage.

6. The blumlein structure of claim 1, wherein the first and third planar conductive strips each end at the end of the blumlein structure at which the electromagnetic pulse is provided in annular electrodes aligned along the axis of particle accelerator.

7. The blumlein structure of claim 1, wherein the resistance of the lossy portion is of the same order of magnitude as the inherent impedance of the Blumlein structure aside from the resistive portion.

8. The blumlein structure of claim 1, wherein the lossy portion is a carbon based resistance formed on the first conductive strip. the third conductive strip or both near the end of the blumlein structure opposite the end from which the electromagnetic pulse is provided.

9. The blumlein structure of claim 1, wherein the lossy portion is a ceramic based resistance formed on the first conductive strip, the third conductive strip or both near the end of the blumlein structure opposite the end from which the electromagnetic pulse is provided.

10. The blumlein structure of claim 1, wherein the lossy portion is a metal film based resistance formed on the first conductive strip, the third conductive strip or both near the end of the blumlein structure opposite the end from which the electromagnetic pulse is provided.

11. The blumlein structure of claim 1, wherein the lossy portion is a volumetric resistance between the first conductive strip and the third conductive strip near the end of the blumlein structure opposite the end from which the electromagnetic pulse is provided.

12. The blumlein structure of claim 11, wherein the volumetric resistance is a carbon based material.

13. The blumlein structure of claim 11, wherein the volumetric resistance is embedded in the dielectric material.

14. The blumlein structure of claim 1, wherein the lossy portion has a frequency dependent absorption and is formed on the first conductive strip, the third conductive strip or both near the end of the blumlein structure opposite the end from which the electromagnetic pulse is provided.

15. The blumlein structure of claim 14, wherein the lossy portion is formed of a ferromagnetic material.

16. The blumlein structure of claim 14, wherein the lossy portion is formed of a ferrimagnetic material.

17. The blumlein structure of claim 1, wherein the one or more of the conductive strips narrow in width from the location where the switch is connected to the end from which the electromagnetic pulse is provided.

18. The blumlein structure of claim 1, wherein the second conductive strip does not extend beyond the switch on the side between the switch and the end opposite from which the electromagnetic pulse is provided.

19. The blumlein structure of claim 1, wherein the portion of the first conductive strip on the side between the switch and the end opposite from which the electromagnetic pulse is provided is narrower than the portion of the first conductive strip on the side between the switch and the end from which the electromagnetic pulse is provided.

20. The blumlein structure of claim 19, wherein the third conductive strip is the same width as the portion of the first conductive strip on the side between the switch and the end opposite from which the electromagnetic pulse is provided.

21. The blumlein structure of claim 1, wherein at least a portion of the first conductive strip between the switch and end of the blumlein structure opposite the end from which the electromagnetic pulse is provided is formed of a resistive sheet.

22. The blumlein structure of claim 21, wherein at least a portion of the third conductive strip is formed of an resistive sheet.

23. A blumlein structure to provide an electromagnetic pulse at an end thereof, comprising:
a first planar conductive strip;
a second planar conductive strip parallel to the first planar conductive strip;
a third planar conductive strip parallel to the first and second planar conductive strip, where the second planar conductive strip is positioned between the first and third planar conductive strips;
a switch with first and second terminals are respectively connected to the first and the second planar conductive strips;
dielectric material filling the space between the first and second and the second and third planar conductive strips;
an electrical connection between the first and third planar conductive strips at an end of the blumlein structure opposite the end from which the electromagnetic pulse is provided; and
a pulse dampening section connected between the first and third conductive strips to provide an additional electrical connection therebetween, where the additional electrical connection includes a lossy portion.

24. The blumlein structure of claim 23, wherein the additional electrical connection is connected to the first and third conductive strips at the end from which electromagnetic pulse is provided.

25. The blumlein structure of claim 24, wherein the first and third conductive strips end in equilibration rings at the end from which electromagnetic pulse is provided, the additional electrical connection being connected to the first and third conductive strips at equilibration rings.

26. The blumlein structure of claim 23, wherein the dimensions of the pulse dampening section are such that the characteristic impendence thereof is of the same order or greater than that of the blumlein structure without the pulse dampening structure.

27. The blumlein structure of claim 23, wherein the width of the pulse dampening section is less than half the width of the first planar conductive strip at the end from which electromagnetic pulse is provided.

28. The blumlein structure of claim 23, wherein the length of the pulse dampening section is approximately the same as the length of the first planar conductive strip from where the switch connected thereto to the end from which electromagnetic pulse is provided.

29. The blumlein structure of claim 23, wherein the pulse dampening section has an electrical length such that reflections therefrom do not distort an initial electromagnetic pulse supplied from the blumlein structure.
